(19) United States
(12) Patent Application Publication
(10) Pub. No.: US 2004/0138770 A1
(43) Pub. Date: Jul. 15, 2004

(54) Audio reproducer suitable to practice musical instrument

(76) Inventors: Yuji Hanabusa, Tokyo (JP); Shigenori Shimokawa, Hanno-Shi (JP); Reiji Yoshida, Tokyo (JP); Hiroshi Nomura, Iruma-Shi (JP)

Correspondence Address: ANDERSON KILL & OLICK, P.C., 1251 Avenue of the Americas, New York, NY, 10020, US

(21) Appl. No.: 10/738,287

(22) Filed: Dec. 16, 2003

(30) Foreign Application Priority Data
Jan. 15, 2003 (JP) 2003-007678

(51) Int. Cl. G06F 17/00; H03G 3/00

(52) U.S. Cl. 700/94; 381/61

(57) ABSTRACT

An audio reproducer that can be preferably used to practice to play a musical instrument is disclosed. The audio reproducer includes an audio reproduction part and a processing part. The audio reproduction part reproduces a first audio signal recorded in a recording medium. The processing part performs a special reproduction operation on the reproduced first audio signal under control over the audio reproduction part as well as a special effect operation on a second audio signal supplied via an input terminal. Then the processing part synthesizes the resulting first audio signal and the resulting second audio signal to generate an output audio signal.

### BACKGROUND OF THE INVENTION

1. Field of the Invention

The present invention generally relates to an audio reproducer, and more particularly to an audio reproducer that reproduces audio information recorded in a recoding medium.

2. Description of the Related Art

When a player practices a musical instrument such as a guitar and a bass guitar, the player conventionally practices the musical instrument by playing the musical instrument synchronously with reproduction of music recorded in a recording medium, which is often called a “copy-playing” approach. If the player obtains a musical score of music that the player wants to copy-play, the player can practice a musical instrument according to the musical score and perform the musical instrument to the tune of the music recorded in a recording medium.

On the other hand, if the player cannot obtain the musical score, the player conventionally practices the musical instrument by repeatedly listening to the music and comprehending keys, pitches, tempos and others of individual played musical instruments, which is called a “ear-copying” approach. This action corresponds to drafting of a musical score or a code score of the music.

In general, however, these approaches have some difficulties. For example, the playing speed of common music may be too high for the ear-copying approach, and the played music may include various types of sounds of musical instruments in use. For these reasons, it is extremely difficult for a player to catch a desired type sound through the conventional approaches. In order to conduct the copy-playing or the ear-copying, the player is required to have sophisticated skills because of the difficulties.

There are some existing loop reproducers designed to make the copy-playing and the ear-copying more convenient. For example, AKAI professional M.I. Corp. produces “Variable Tempo/Constant Pitch Phrase Recorder RIFF-O-MATIC U400” as such a loop reproducer. This apparatus fetches an audio signal from a CD player or another sound source via an external input terminal in accordance with timing of operation buttons. Then, the apparatus loop-reproduces the fetched audio signal and changes the pitch and the key of the audio signal so as to easily catch a desired sound.

However, such a loop reproducer fetches an audio source in the form of an analog audio signal from a commonly used CD player. Here, since the loop reproducer and the CD player are separately provided, a user needs to manipulate these two apparatuses separately. For this reason, when the loop reproducer fetches the audio source from the CD player at an extremely short interval, it is difficult to determine timing to designate a start point and an end point of loop reproduction.

Furthermore, after the fetched sound is loop-reproduced and a desired phrase of the sound is caught, the user may often expect to ear-copy the next phrase.

In this case, the loop reproducer needs to fetch the audio signal from the CD player again, and thus the CD player has to be paused. The player needs to pause the CD player immediately after fetching of a phrase to the loop reproducer.

In the conventional loop reproducer, a player is required to perform the above-mentioned troublesome operations in order to conduct the copy-playing and the ear-copying.

### SUMMARY OF THE INVENTION

It is a general object of the present invention to provide an audio reproducer in which the above-mentioned problems are eliminated.

A more specific object of the present invention is to provide an audio reproducer suitable to practice musical instruments.

In order to achieve the above-mentioned objects, there is provided according to one aspect of the present invention an audio reproducer, including: an audio reproduction part reproducing a first audio signal recorded in a recording medium; and a processing part performing a special reproduction operation on the reproduced first audio signal under control over the audio reproduction part as well as a special effect operation on a second audio signal supplied via an input terminal, synthesizing the resulting first audio signal and the resulting second audio signal to generate an output audio signal.

In an embodiment of the present invention, the audio reproducer may further include an instruction part issuing an instruction for the special reproduction operation and/or an instruction for the special effect operation together with a level of the special effect operation to the processing part.

In an embodiment of the present invention, the audio reproduction part and the processing part may be integrally configured.

In an embodiment of the present invention, the audio reproduction part may reproduce digital audio data from the recording medium, and the processing part may digitally process the digital audio data and perform the special reproduction operation on the digitally processed digital audio data.

In an embodiment of the present invention, the processing part may detect a difference between a key of the second audio signal and a reference key.

In an embodiment of the present invention, the audio reproducer may further include a display part displaying the difference between the key of the second audio signal and the reference key.

In an embodiment of the present invention, the audio reproducer may further include an analog-digital converter converting an analog audio signal supplied via the input terminal into digital audio data.

In an embodiment of the present invention, the processing part may digitally process the digital audio data and perform the special effect operation on the digitally processed digital audio data.

In an embodiment of the present invention, the processing part may digitally perform the special reproduction operation on the first audio signal to generate first digital audio data and the special effect operation on the second audio signal to generate second digital audio data, and digitally synthesizes the first and second digital audio data to generate a synthesized digital audio data.

In an embodiment of the present invention, the audio reproducer may further include a digital-analog converter, in response to receipt of the synthesized digital audio data from the processing part, converting the synthesized digital audio data into an output analog audio signal.

In an embodiment of the present invention, the special reproduction operation may include at least one of a loop reproduction, a key change reproduction, a pitch change reproduction and a tempo change reproduction.

In an embodiment of the present invention, the audio reproduction part and the processing part may be detachable each other.

In an embodiment of the present invention, the input terminal may receive an audio signal generated by playing a musical instrument.

According to one aspect of the present invention, while a special reproduction operation is performed on an audio signal reproduced by the audio reproduction part under control over the audio reproduction part, a special effect operation is performed on an audio signal supplied via the input terminal. Then, the two audio signals are, synthesized and supplied. As a result, it is possible to continuously reproduce the audio signal even during the special reproduction. In addition, since a special effect operation is performed on an audio signal from a musical instrument and the two audio signals are synthesized and output, the present invention makes it possible for a user to manipulate an inventive audio reproducer more easily and conveniently for the purpose of copy-playing and ear-copying.

Other objects, features and advantages of the present invention will become more apparent from the following detailed description when read in conjunction with the accompanying drawings.

### BRIEF DESCRIPTION OF THE DRAWINGS

FIG. 1 is a block diagram illustrating a structure of an exemplary system according to the present invention;

FIG. 2 is a block diagram illustrating an exemplary structure of a digital audio reproducer according to an embodiment of the present invention;

FIG. 3 is a block diagram illustrating an exemplary functional structure of a digital data processing circuit according to the embodiment;

FIG. 4 is a diagram to explain an exemplary operation of an output switch part according to the embodiment;

FIG. 5 is a diagram illustrating an exemple displayed by a display part during a tuning operation according to the embodiment;

FIG. 6 is a top view of the digital audio reproducer according to the embodiment;

FIG. 7 is a right side view of the digital audio reproducer according to the embodiment;

FIG. 8 is a front view of the digital audio reproducer according to the embodiment;

FIG. 9 is a rear view of the digital audio reproducer according to the embodiment; and

FIG. 10 is a diagram illustrating an exemplary structure of a digital audio reproducer according to another embodiment of the present invention.

### DETAILED DESCRIPTION OF THE PREFERRED EMBODIMENTS

In the following, embodiments of the present invention will be described with reference to the accompanying drawings.

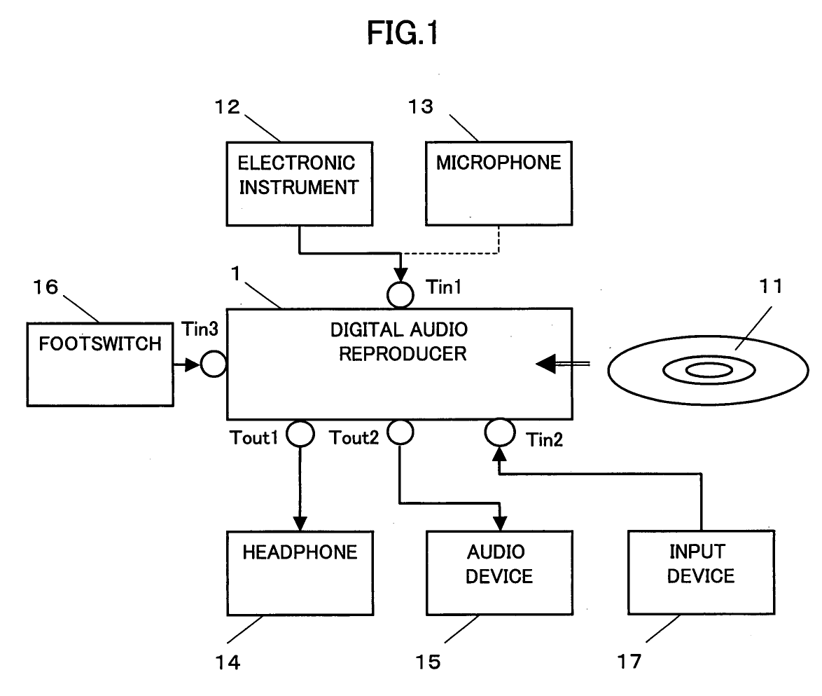

A description is given, with reference to FIG. 1, of a system in which a digital audio data reproducer according to an embodiment of the present invention is used.

FIG. 1 is a block diagram illustrating a structure of an exemplary system according to the present invention.

Referring to FIG. 1, a digital audio data reproducer 1 according to an embodiment of the present invention is connected to an electronic instrument 12, a microphone 13, a headphone 14, an audio device 15, a footswitch 16 and other input devices 17 such as a keyboard. The digital audio data reproducer 1 can reproduce an audio CD (Compact Disc), mix the reproduced sound with an input sound generated by playing of the electronic instrument 12 or supplied from the microphone 13, and supply the resulting sound to the headphone 14 or the audio device 15. Here, the digital audio data reproducer 1 includes a built-in effector that can effect the input sound from the electronic instrument 12 or the microphone 13. It is noted that the electronic instrument 12 may be an electronic guitar, an electronic bass guitar, and so on.

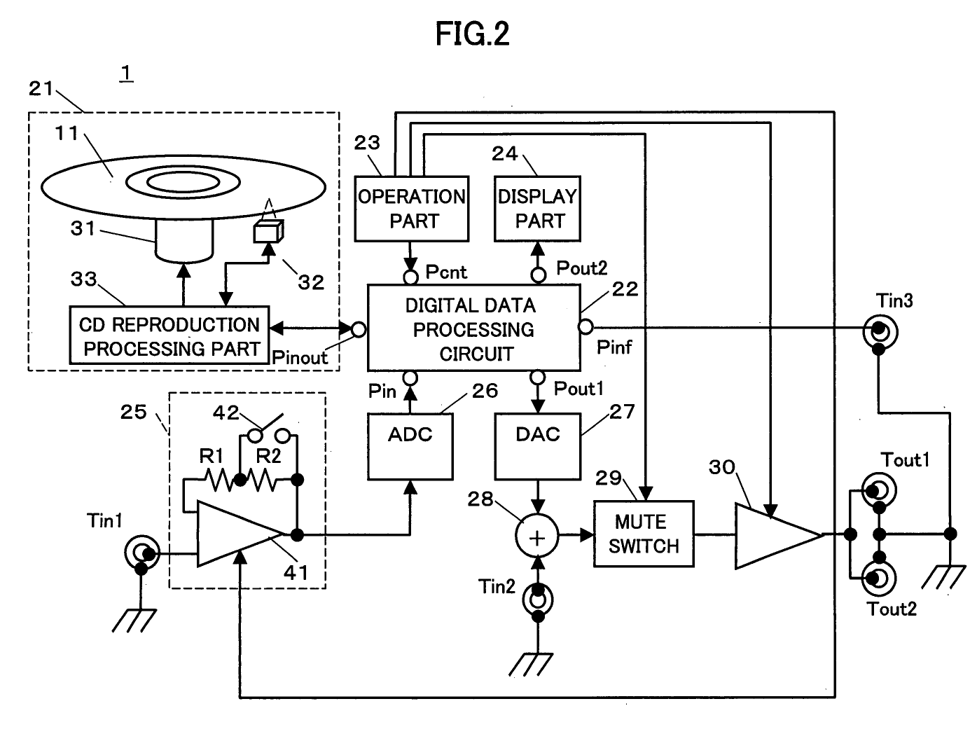

A description is given, with reference to FIG. 2 through FIG. 9, of the digital audio data reproducer 1 according to the embodiment.

FIG. 2 is a block diagram illustrating an exemplary structure of the digital audio data reproducer 1.

Referring to FIG. 2, the digital audio reproducer 1 comprises a CD reproduction part 21, a digital data processing circuit 22, an operation part 23, a display part 24, an input amplifier 25, an analog-digital converter (ADC) 26, a digital-analog converter (DAC) 27, an analog signal synthesis part 28, a mute switch 29 and an output amplifier 30. These components are integrally incorporated in a housing of the digital audio reproducer 1.

The audio CD 11 can be loaded and unloaded into the CD reproduction part 21. The CD reproduction part 21 comprises a spindle motor 31, a pickup 32 and a CD reproduction processing part 33 as illustrated in FIG. 2. For example, the CD reproduction part 21 is embodied by a CD-ROM drive having an ATAPI (AT Attachment Packet Interface) interface or an ordinary CD player, so-called, an audio CD drive. The CD reproduction part 21 can reproduce audio data of the audio CD 11 at an n times speed.

In the CD reproduction part 21, the spindle motor 31 rotates the audio CD 11. The pickup 32 catches a reproduction signal that results from the reproduction of the audio CD 11. The CD reproduction processing part 33 decodes the reproduction signal into reproduction data. The reproduction data are supplied to the digital data processing circuit 22 via an ATIPI interface or a simple audio interface. It is noted that the CD reproduction part 21 is configured to communicate to the digital data processing circuit 22, for example, via the ATAPI interface.

The electronic instrument 12 is connected to an input terminal Tin1. An analog audio signal is supplied to the input terminal Tin1 from the electronic instrument 12. The supplied analog audio signal, in turn, is supplied to the input amplifier 25.

As shown in FIG. 2, the input amplifier 25 comprises an amplifier circuit 41, feedback resistances R1 and R2, and a gain switch 42. In the input amplifier 25, a gain can be switched by switching of the gain switch 42. For example, the gain switch 42 is used to switch Connections of the input terminal Tin1 between the electronic instrument 12 and the microphone 13. When the gain switch 42 connects the input terminal Tin1 to the electronic instrument 12, the input amplifier 25 sets the gain to a level most suitable for the electronic instrument 12. On the other hand, when the gain switch 42 connects the input terminal Tin1 to the microphone 13, the input amplifier 25 sets the gain to a level most suitable for the microphone 13.

In the amplifier circuit 41, the gain is adjusted in accordance with instructions from the operation part 23. It is possible to adjust the level of the analog audio signal supplied to the input terminal Tin1 in accordance with user's manipulation of the manipulation part 23.

The amplified analog audio signal, in turn, is supplied to the analog-digital converter 26. The analog-digital converter 26 converts the amplified analog audio signal into digital data. Then, the resulting digital data is supplied to an input port Pin of the digital data processing circuit 22.

The digital data processing circuit 22 is configured, for example, from a specific DSP (Digital Signal Processor). The digital data processing circuit 22 receives various instructions from the operation part 23, performs the corresponding operations, which are described below, on reproduction data from the CD reproduction part 21, and outputs the resulting data. Also, the digital data processing circuit 22 effects an audio signal provided from the electronic instrument 12 or the microphone 13 via the input terminal Tin1. Then, the digital data processing circuit 22 digitally synthesizes these resulting data.

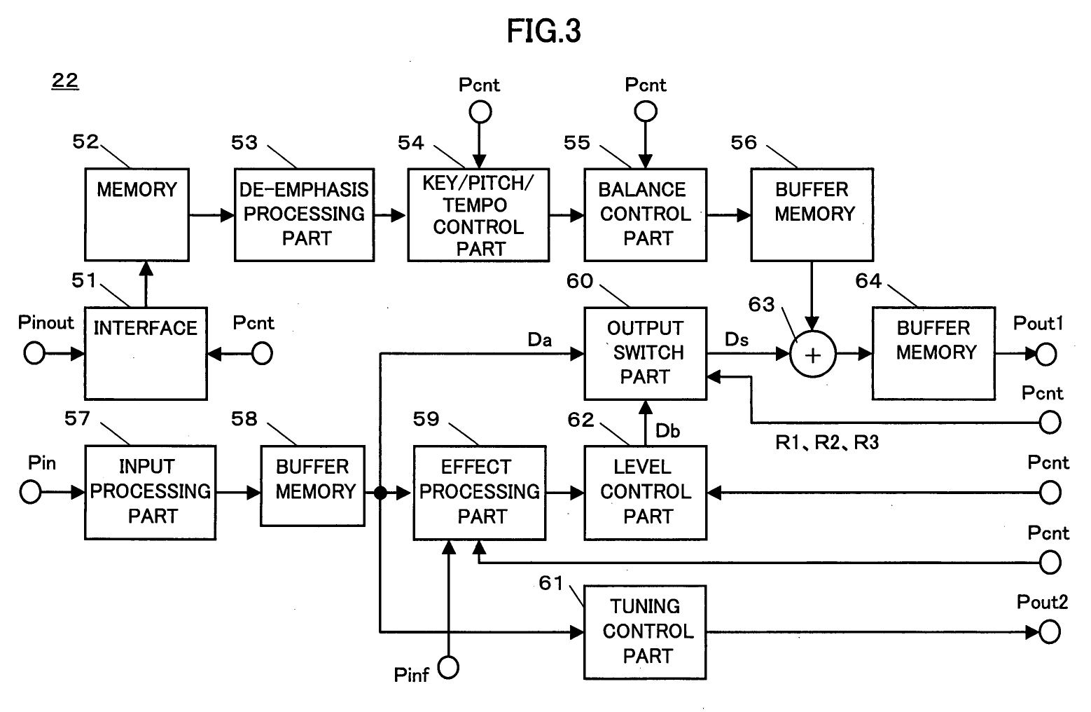

FIG. 3 is a block diagram illustrating an exemplary functional structure of the digital data processing circuit 22.

Referring to FIG. 3, the digital data processing circuit 22 comprises an interface 51, a memory 52, a de-emphasis processing part 53, a key/pitch/tempo control part 54, a balance control part 55, buffer memories 56, 58, and 64, an input processing part 57, an effect processing part 59, an output switch part 60, a tuning control part 61, a level control part 62, and a digital data synthesis part 63. Here, the memory 52 and the buffer memories 56, 58 and 64 may be configured, for example, from external RAMs.

The interface 51 controls communication to the CD reproduction part 21 via an input/output port Pinout. Based on instructions from the operation part 23 and the capacity of the memory 52, the interface 51 provides an operational control instruction to the CD reproduction part 21 as well as controls accumulation of reproduction data in the memory 52.

The memory 52 is configured as a ring type memory and works as an anti-shock memory. In the memory 52, reproduction data resulting from reproduction of the CD reproduction part 21 are stored up to a predetermined data amount. Since the memory 52 is configured as a ring type memory, it is possible to realize an ordinary sequential reproduction as well as loop reproduction.

Here, when digital audio data from the CD reproduction part 21 are accumulated in the memory 52 at the time of reproduction, the interface 51 reads the digital audio data from the memory 52 at an arbitrary reproduction speed. At this time, since the memory 52 is configured as a ring type memory, the interface 51 instructs the CD reproduction part 21 to perform a reproduction operation and a pause operation alternately corresponding to increases and decreases in the amount of the digital audio data accumulated in the memory 52 for the purpose of execution of a known intermittent reproduction operation. In this manner, a constant amount of successive digital audio data is accumulated in the memory 52 at any time.

In this configuration, it is possible to perform special reproduction without execution of operations for the special reproduction and the CD reproduction part 21 separately and continuously reproduce the audio CD 11. Accordingly, it is possible to make manipulation for the copy-playing and the ear-copying easier.

The reproduction data in the memory 52 is supplied to the de-emphasis processing part 53. The de-emphasis processing part 53 performs a de-emphasis operation on the reproduction data from the memory 52.

The de-emphasized reproduction data are supplied to the key/pitch/tempo control part 54. On the other hand, the key/pitch/tempo control part 54 receives a key/pitch/tempo control instruction from the operation part 23. Based on the key/pitch/tempo control instruction, the key/pitch/tempo control part 54 performs the corresponding operation on the de-emphasized reproduction data. The key/pitch/tempo control part 54 is configured to adjust the key, the pitch and the tempo of the reproduction data separately based on the key/pitch/tempo control instruction. For example, the key/pitch/tempo control part 54 may be configured to change the tempo under a fixed key or change the key and the pitch under a fixed tempo.

The key/pitch/tempo control part 54 supplies the resulting reproduction data to the balance control part 55. On the other hand, the balance control part 55 receives a balance control instruction from the operation part 23. Based on the balance control instruction, for example, the balance control part 55 adjusts a reproduction level of the reproduction data to control the level balance of input signals from the input terminals Tin1 and Tin2. The balanced reproduction data are stored in the buffer memory 56.

On the other hand, audio data corresponding to a audio signal originating from the electronic instrument 12 or the microphone 13 are supplied from the analog-digital converter 26 to the input processing part 57. The input processing part 57 converts monaural audio data, which are supplied from the analog-digital converter 26, into stereo audio data. The resulting audio data are stored in the buffer memory 58. Then, the audio data in the buffer memory 58 are supplied to the effect processing part 59, the output switch part 60 and the tuning control part 61.

The effect processing part 59 fetches the audio data from the buffer memory 58 and performs an effect operation on the audio data based on an effect operation instruction from the operation part 23. For example, operations set in an effector of an electric guitar are available in the effect operation. In the effect operation, a distortion parameter, a compressor parameter, a tone control parameter, a flanger parameter, a reverb parameter, a delay parameter, a phaser parameter, an exciter parameter, a pitch shifter parameter, a chorus parameter, a tremolo parameter, a vibrato parameter and an auto-wah parameter are set. Furthermore, the effect processing part 59 can perform various effect operations on an audio signal supplied from the microphone 13.

An input port Pinf is connected to the effect processing part 59. The input port Pinf is connected to an input terminal Tin3. The footswitch 16 is connected to the input terminal Tin3.

The effect processing part 59 monitors a status of a signal supplied to the input port Pinf. The effect processing part 59 is configured to switch the effect operation ON/OFF based on an operation signal corresponding to user's manipulation of the footswitch 16.

In this configuration, the effect processing part 59 can perform the same special effect as an ordinary guitar effector on an audio signal supplied from the input terminal Tin1 and then output the resulting audio signal. Also, when the CD reproduction part 21 does not reproduce the audio CD 11, it is possible to use the effect processing part 59 as an ordinary guitar effector.

It is noted that the effect operation of an audio reproducer according to the present invention is not limited to the above-mentioned effect operation and other various operations can be performed.

The effected audio data are supplied to the level control part 62. On the other hand, the level control part 62 receives an effect operation level control instruction from the operation part 23. Based on the effect operation level control instruction, the level control part 62 controls an output level of the effected audio data. Then, the resulting audio data are supplied to the output switch part 60.

The output switch part 60 receives a switch instruction from the operation part 23. Based on the switch instruction, the output switch part 60 switches between audio data Da supplied from the buffer memory 58 directly and effected audio data Db supplied from the level control part 62 and outputs the selected audio data.

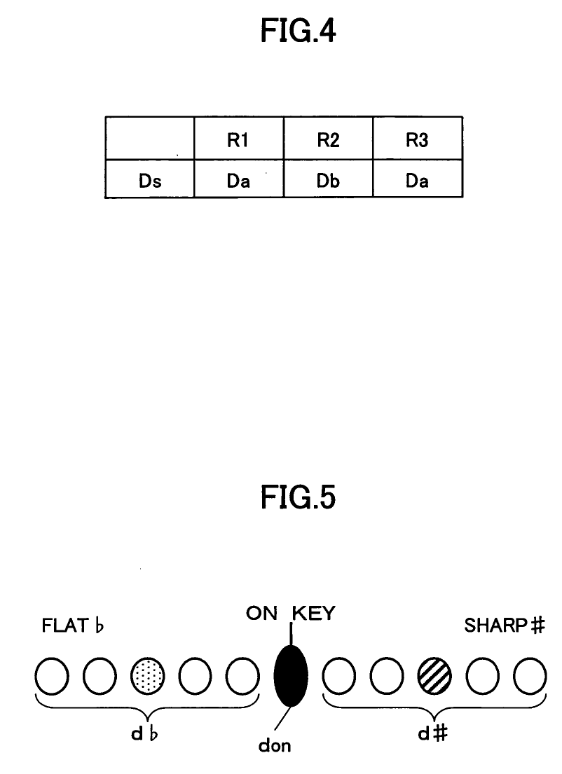

FIG. 4 is a diagram to explain the output switch part 60 according to the embodiment.

Referring to FIG. 4, if the switch instruction from the operation part 23 is an instruction R1 not to perform any effect operation, the output switch part 60 outputs the audio data Da in the buffer memory 58 as the selected audio data Ds. In contrast, if the switch instruction from the operation part 23 is an instruction R2 to perform an effect operation, the output switch part 60 outputs the audio data Db supplied from the level control part 62 as the selected audio data Ds. Furthermore, if the switch instruction from the operation part 23 is an instruction R3 to perform a tuning operation in the tuning control part 61, the output switch part 60 outputs the audio data Da in the buffer memory 58 as the selected audio data Ds because non-effected audio data have to be provided.

The selected audio data Ds are supplied to the digital data synthesis part 63. The digital data synthesis part 63 synthesizes audio data in the buffer memory 56 and the selected audio data Ds. The resulting audio data are stored in the buffer memory 64. The audio data in the buffer memory 64 are supplied via an output port Pout1.

The tuning control part 61 receives the audio data in the buffer memory 58 and controls tuning of a guitar, for example. The tuning control part 61 compares the key of the audio data supplied from the buffer memory 58 to a reference key, and supplies tuning data corresponding to the difference to the display part 24.

The display part 24 is disposed on an operation panel P and is configured, for example, from a LCD (Liquid Crystal Device) panel. Various information items on the audio CD 11 reproduced by the CD reproduction part 21, such as the number of songs, a reproduction time, a remaining time and an operational mode, are displayed on the display part 24. During the tuning operation, the key difference is displayed based on tuning data.

FIG. 5 shows an exemplary display part 24 during a tuning operation according to the embodiment.

Referring to FIG. 5, when the display part 24 receives tuning data such that a difference between the key of audio data from the buffer memory 58 and a reference key is zero, the display part 24 displays a dot don to represent “onkey”. On the other hand, if the key of the audio data from the buffer memory 58 deviates from the reference key to the flat, the display part 24 displays a dot d corresponding to the difference in the flat direction. Furthermore, if the key of the audio data from the buffer memory 58 deviates from the reference key to the sharp, the display part 24 displays a dot # corresponding to the difference in the sharp direction.

The tuning control part 61 has two tuning modes: an auto mode and a manual mode.

In the auto mode, the tuning control part 61 automatically recognizes where the key should be tuned based on the key of the audio data from the buffer memory 58, and sets the reference key. On the other hand, in the manual mode, the tuning part 61 sets the reference key based on user's manipulation of the operation part 23.

Audio data from the output port Pout1 are supplied to the digital-analog converter 27. The digital-analog converter 27 converts digital audio data from the digital data processing circuit 22 into an analog audio signal.

The converted analog audio signal is supplied to the analog signal synthesis part 28. On the other hand, the analog signal synthesis part 28 receives an analog audio signal from the input terminal Tin2. The analog signal synthesis part 28 synthesizes the converted analog audio signal and the analog audio signal from the input terminal Tin2 and then outputs the resulting analog audio signal. The synthesized analog audio signal is supplied to the mute switch 29.

The mute switch 29 receives a mute instruction from the operation part 23. The mute switch 29 controls an output of the analog audio signal by switching ON/OFF corresponding to the mute instruction. The output analog audio signal is supplied to the output amplifier 30.

The output amplifier 30 receives an output level control instruction from the operation part 23. The output amplifier 30 adjusts gain corresponding to the output level control instruction so as to control the level of the output analog audio signal. The output analog audio signal is supplied to the output terminals Tout1 and Tout2. Each of the output terminals Tout1 and Tout2 is configured, for example, from a stereo mini jack. In this embodiment, the output terminals Tout1 and Tout2 are connected to the headphone 14 and the audio device 15, respectively, as illustrated in FIG. 1.

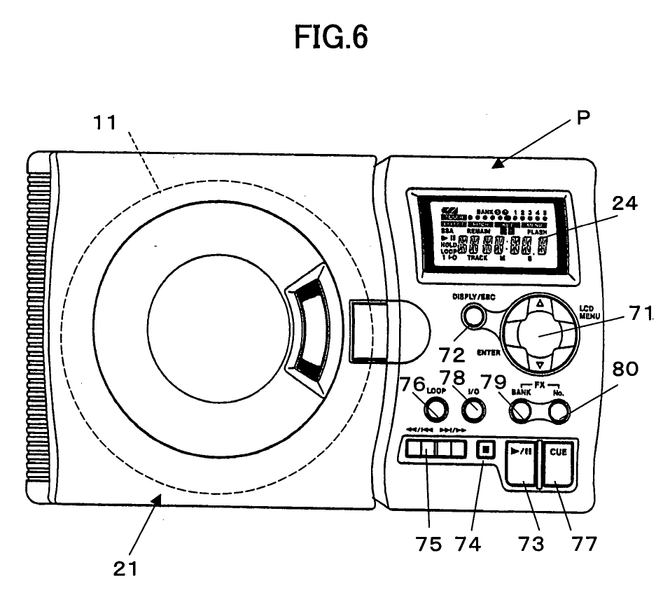

Next, the operation part 23 is described in detail with reference to FIG. 6 through FIG. 9.

FIG. 6 is a top view of the digital audio reproducer 1 according to the embodiment.

Referring to FIG. 6, the operation part 23 comprises a cross-shaped cursor key 71, a display/escape key button 72, a reproduction/pause button 73, a stop button 74, a skip/search button 75, a loop button 76, a cue button 77, a loop designation button 78, an effect bank designation button 79 and an effect number designation button 80.

By manipulating the cross-shaped cursor key 71, a user can designate a desired effect type where the digital data processing circuit 22 should effect an audio signal supplied from a musical instrument such as a guitar via the input terminal Tin1. In addition, the user can change the key, the pitch and the tempo of an audio signal reproduced by the CD reproduction part 21. Furthermore, the user call an instrument tuner function to tune an musical instrument such as a guitar/bass guitar that supplies an audio source to the input terminal Tin1 and then provides some instruction to execute the instrument tuner function. Furthermore, the user can designate a reproduction mode of the CD reproduction part 21. For example, the user can designate whether the CD reproduction part 21 should loop-reproduce all songs of a given audio CD.

By manipulating the display/escape button 72 together with the cross-shaped cursor key 71, the user can provide an escape instruction to escape from a status where the digital audio reproducer 1 is subject to a given instruction after execution of the instruction. When the user presses the display/escape button 72 in a normal status of the digital audio reproducer 1, it is possible to display reproduction time of the audio CD 11 in selected form of track elapsed time, track remaining time or total remaining time.

The reproduction/pause button 73 and the stop button 74 are configured similarly to that of an existing CD player. Through the reproduction/pause button 73 and the stop button 74, the user can instruct the CD reproduction part 21 to reproduce, pause or stop the audio CD 11.

The skip/search button 75 is also configured similarly to a cue/review/track skip button of an existing CD player. Through the skip/search button 75, the user can shift the reproduction position of a track reproduced by the CD reproduction part 21 together with the reproduction sound or skip a target track to the previous track or the next track thereof as through a cue/review/track skip button of an existing CD player.

The loop button 76 is used to instruct the digital audio reproducer 1 to perform a repeat reproduction operation.

In a status where the repeat reproduction operation is set through the loop button 76, if the user double-presses the loop designation button 78 during reproduction in the CD reproduction part 21, the user can designate a portion of the audio CD 11 that the user wants the digital audio reproducer 1 to reproduce over listening to the reproduced sound. In detail, when the user presses the loop designation button 78 one time, the address of a currently reproduced portion of the audio CD 11 is set as the start position of the repeat reproduction. Then, when the user presses the loop designation button 78 one more time, the address of a currently reproduced portion of the audio CD 11 is set as the end position of the repeat reproduction. These addresses are stored in the memory 52, and a portion of digital audio data in the memory 52 included between the two addresses are loop-reproduced in the digital data processing circuit 22.

The cue button 77 is used to designate cue reproduction. When the user presses the reproduction/pause button 73, the current address of the audio CD 11 is stored in the memory 52. Then, when the user presses the cue button 77, the digital audio reproducer 1 returns to the stored address, and can reproduce the audio CD 11 from the portion corresponding to the address or pause the reproduction at the portion.

Also, while the user listens to a track reproduced by the CD reproduction part 21, the user can store the current address in the memory 52 by pressing the reproduction/pause button 73 to pause the reproduction and then pressing the reproduction/pause button 73 one more time. Through this manipulation, it is possible to change the start position of the cue reproduction.

By manipulating the effect bank designation button 79 and the effect number designation button 80, the user can call a desired effect function from effect programs stored in a program memory built-in the digital data processing circuit 22 and temporarily store the effect function.

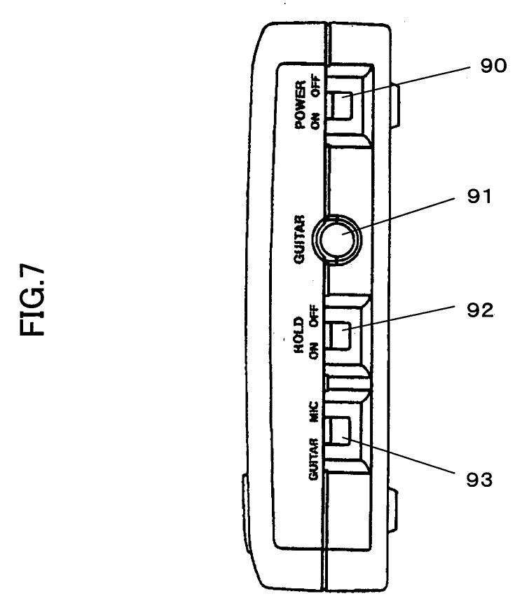

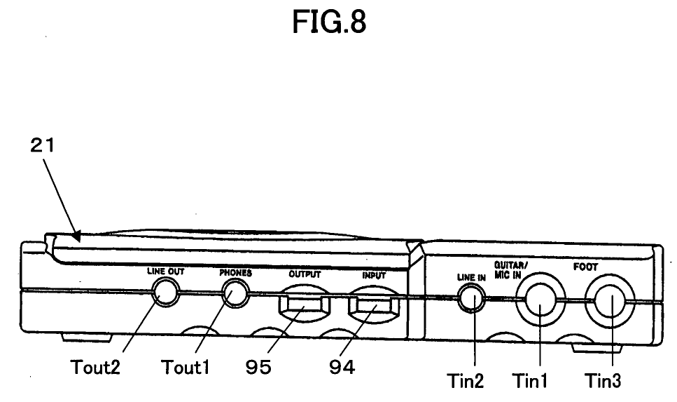

FIG. 7 is a right side view of the digital audio reproducer 1 according to the embodiment. FIG. 8 is a front view of the digital audio reproducer 1 according to the embodiment.

Referring to FIG. 7, the operation part 23 further comprises a power switch 90, a guitar switch 91, a hold switch 92 and a guitar/microphone switch 93, which are provided in the right side of the housing.

Referring to FIG. 8, the operation part 23 further comprises an input level switch 94 and an output level switch 95, which are provided in the front side of the housing. Furthermore, the input terminals Tin1 through Tin3 and the output terminals Tout1 and Tout2 are provided in the front side of the housing.

The power switch 90 is for power ON/OFF. The guitar switch 91 is used to operate the CD reproduction part 21 as a normal CD player. When the user switches the guitar switch 91 OFF, the digital audio reproducer 1 stops supplying electricity to the input amplifier 25 and the analog-digital converter 26 as well as instructs the digital data processing circuit 22 to only control operations of the CD reproduction part 21. At this time, the digital data processing circuit 22 becomes a power-save status.

The hold switch 92 is for permission control of input operations of all operation buttons on the operation panel P. In particular, when the CD reproduction part 21 is used as a normal portable CD player, the hold switch 92 is used to prevent accidental manipulation.

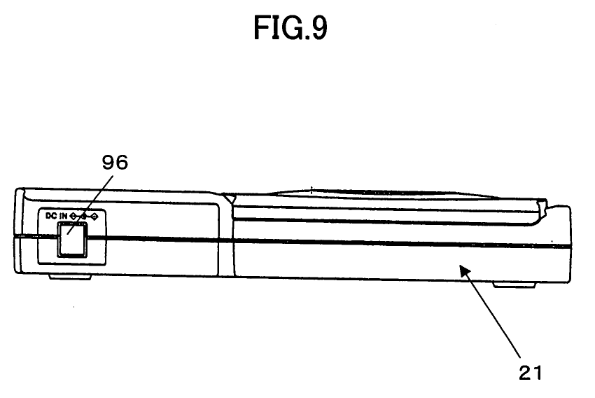

FIG. 9 is a rear view of the digital audio reproducer 1 according to the embodiment.

Referring to FIG. 9, a power supply connector 96 is provided in the rear side of the housing. The power supply connector 96 receives direct electricity from an AC adaptor. The digital audio reproducer 1 is driven by the direct electricity from the AC adaptor. Alternatively, the digital audio reproducer 1 may be driven by a battery.

An operation of the digital audio reproducer 1 is described herein.

When a user presses the reproduction/pause button 73 on the operation panel P, a reproduction instruction is sent to the digital data processing circuit 22. The digital data processing circuit 22 issues a reproduction instruction to the CD reproduction part 21 to reproduce the audio CD 11, which is loaded into the CD reproduction part 21, from the first track thereof corresponding to user's manipulation of the reproduction/pause button 73. In response to receipt of the reproduction instruction from the digital data processing circuit 22, the CD reproduction part 21 reproduces the first track of the audio CD 11 twice of a normal speed and supplies the reproduced digital audio data to the audio data processing circuit 22.

In response to receipt of the audio digital data from the CD reproduction part 21, the digital audio processing circuit 22 stores the digital audio data in the memory 52. At the same time, the digital audio processing circuit 22 reads the digital audio data from the memory 52 and supplies the read digital audio data to the de-emphasis processing part 53. The digital data processing circuit 22 always monitors for a data storage status of the memory 52 and repeatedly issues reproduction instructions and pause instructions alternately to the CD reproduction part 21 so as to perform a known intermittent reproduction operation.

When the user manipulates the cross-shaped cursor key 71 on the operation panel P to change the key, the pitch or the tempo of the reproduced track, the digital data processing circuit 22 performs a key change operation, a pitch change operation or a tempo change operation on the read digital audio data by controlling the key/pitch/tempo control part 54.

On the other hand, an audio signal originating from a musical instrument such as a guitar via the input terminal Tin1 is supplied to the analog-digital converter 26 via the input amplifier 25 to convert he input audio signal into digital audio data. Then, the digital audio data supplied to the digital data processing circuit 22. The digital data processing circuit 22 performs an effect operation on the digital audio data corresponding to designation of the user.

The digital data processing circuit 22 mixes the effected digital audio data with the above-mentioned digital audio data resulting from the key change operation, the pitch change operation or the tempo change operation, and supplies the resulting digital audio data to the digital-analog converter 27.

At this time, the digital data processing circuit 22 has just performed the mixing operation on the audio signal resulting from the special reproduction operation on the audio signal supplied from the CD reproduction part 21 to the memory 52 and the effected audio signal originating from the musical instrument.

In the above special reproduction status where the audio data are loop-reproduced or the key, the pitch or the tempo of the audio data are changed, when the user presses the loop button 76, the digital data processing circuit 22 waits for inputting of start and end positions of the loop.

In this status, if the user presses the loop designation button 78 twice, the digital data processing circuit 22 stores a current address of the audio CD 11 as start and end positions of repeat reproduction in the memory 52.

When the end position of the repeat reproduction is stored, the digital data processing circuit 22 issues to the CD reproduction part 21 a repeat reproduction instruction to repeat the audio CD 11 from the start position of the repeat reproduction. At this time, the digital data processing circuit 22 has just performed the mixing operation on the audio signal resulting from the special reproduction operation on the audio signal supplied from the CD reproduction part 21 to the memory 52 and the effected audio signal originating from the musical instrument.

According to one aspect of the digital audio reproducer 1, since the single digital data processing circuit 22 performs the special reproduction operation on audio data from the audio CD 11, the effect operation on audio data from the musical instrument such as a guitar, and the mixing operation on the audio data originating from two audio sources, the digital audio reproducer 1 can reproduce in the above special fashion a track that the user wants to copy-play or ear-copy. Synchronously with the reproduced sound, the user can play a musical instrument in a tone similar to that generated by the musical instrument and check the sound. As a result, it is possible to check the key and pitch of the reproduced sound generated from the musical instrument more reliably.

Therefore, the digital audio reproducer according to the embodiment can effectively works as a tool to help a user to practice a musical instrument and ear-copy sounds.

It is noted that the key/pitch/tempo control part 54 may adjust one or both of the keys or the pitches of an audio signal originating from a musical instrument and an audio signal reproduced by the CD reproduction part 21 such that the keys and the pitches automatically coincide.

In addition, the digital audio reproducer 1 according to the embodiment is configured to accommodate the CD reproduction part 21 and the circuit to perform a special reproduction operation and a special effect operation in the same housing. However, the CD reproduction part 21 and the circuit may be separately disposed.

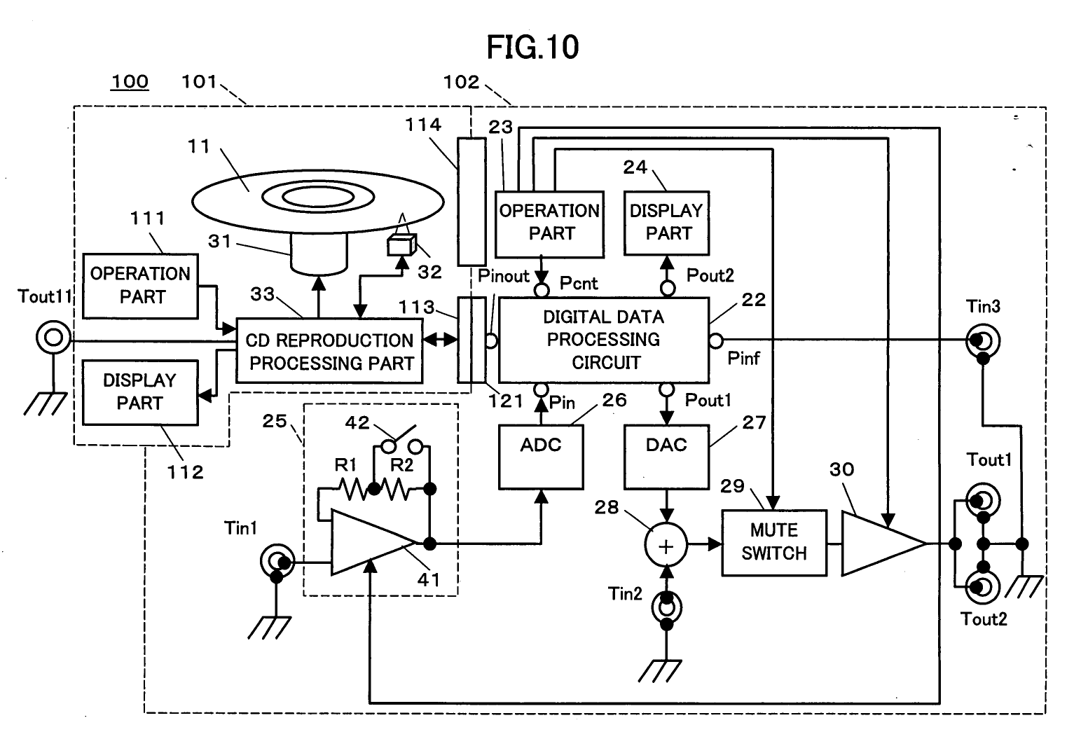

A description is given, with reference to FIG. 10, of an audio reproducer according to another embodiment of the present invention.

FIG. 10 is a block diagram of an exemplary audio reproducer 100 according to the embodiment. In FIG. 10, the same components as those in FIG. 2 are designated by the same reference numerals and the description thereof is omitted.

Referring to FIG. 10, the audio reproducer 100 comprises a CD reproducer 101 and a special processing device 102.

The CD reproducer 101 comprises a spindle motor 31, a pickup 32, a CD reproduction processing part 33, an operation part 111, a display part 112, a connector 113 and a connection mechanism 114. The CD reproducer 101 reproduces the audio CD 11 independently of the special processing device 102 through user's manipulation of the operation part 111. After conversion of the reproduced data into an analog signal by means of a digital-analog converter and other components, the analog signal is supplied via an audio output terminal Tout1. The audio output terminal Tout1 is connected to a headphone 14 and other components.

On the other hand, a connector 121, which can be connected to a connector 113, is provided in the special processing device 102. The connector 121, which complies an interface between the CD reproducer 101 and the special processing device 102, is connected to an I/O port Pinout of the digital data processing circuit 22. The digital data processing circuit 22 and the CD reproducer 101 communicate each other via the connector 121, and the CD reproducer 101 is controlled in cooperation with a special reproduction operation.

Also, the connection mechanism 114 makes the CD reproducer 101 and the special processing device 102 detachable each other. In this embodiment, each of the CD reproducer 101 and the special processing device 102 accommodates a power supply, and can be driven separately.

According to one aspect of the audio reproducer 100, it is possible to use the CD reproducer 101 and the special processing device 102 independently.

In the above-mentioned embodiments, a CD reproducer to reproduce a CD is used as an audio source for a special reproduction operation. However, the present invention is not limited to the embodiments. The present invention may be implemented by a reproducer to reproduce other recording media such as MD (Mini Disk), DVD (Digital Versatile Disk) and a cassette tape. Furthermore, the present invention is applicable to a device having a recording function such as a CD-R (Compact Disk-Recordable) drive, a CD-RW (Compact Disk-ReWritable) drive and a DVD-RAM (Digital Versatile Disk-Random Access Memory) drive. In such a case, it is possible to record a processed audio signal.

According to one aspect of the present invention, while a special reproduction operation is performed on an audio signal reproduced by an audio reproduction part under control of the audio reproduction part, a special effect operation is performed on an audio signal supplied via an input terminal. Then, the two audio signals are synthesized and supplied. As a result, it is possible to continuously reproduce the audio signal even during the special reproduction. In addition, since a special effect operation is performed on an audio signal from a musical instrument and the two audio signals are synthesized and output, the present invention makes it possible for a user to manipulate an inventive audio reproducer more easily and conveniently for the purpose of copy-playing and ear-copying.

The present invention is not limited to the specifically disclosed embodiments, and variations and modifications may be made without departing from the scope of the present invention.

The present application is based on Japanese priority application No. 2003-007678 filed Jan. 15, 2003, the entire contents of which are hereby incorporated by reference.

What is claimed is:

1. An audio reproducer, comprising:
an audio reproduction part reproducing a first audio signal recorded in a recording medium; and
a processing part performing a special reproduction operation on the reproduced first audio signal under control over the audio reproduction part as well as a special effect operation on a second audio signal supplied via an input terminal, synthesizing the resulting first audio signal and the resulting second audio signal to generate an output audio signal.

2. The audio reproducer as claimed in claim 1, further comprising an instruction part issuing to the processing part an instruction for the special reproduction operation together with a level of the special reproduction operation and/or an instruction for the special effect operation together with a level of the special effect operation.

3. The audio reproducer as claimed in claim 1, wherein the audio reproduction part and the processing part are integrally configured.

4. The audio reproducer as claimed in claim 1, wherein the audio reproduction part reproduces digital audio data from the recording medium, and the processing part digitally processes the digital audio data and performs the special reproduction operation on the digitally processed digital audio data.

5. The audio reproducer as claimed in claim 1, wherein the processing part detects a difference between a key of the second audio signal and a reference key.

6. The audio reproducer as claimed in claim 5, further comprising a display part displaying the difference between the key of the second audio signal and the reference key.

7. The audio reproducer as claimed in claim 1, further comprising an analog-digital converter converting an analog audio signal supplied via the input terminal into digital audio data.

8. The audio reproducer as claimed in claim 7, wherein the processing part digitally processes the digital audio data and performs the special effect operation on the digitally processed digital audio data.

9. The audio reproducer as claimed in claim 1, wherein the processing part digitally performs the special reproduction operation on the first audio signal to generate first digital audio data and the special effect operation on the second audio signal to generate second digital audio data, and digitally synthesizes the first and second digital audio data to generate a synthesized digital audio data.

10. The audio reproducer as claimed in claim 9, further comprising a digital-analog converter, in response to receipt of the synthesized digital audio data from the processing part, converting the synthesized digital audio data into an output analog audio signal.

11. The audio reproducer as claimed in claim 1, wherein the special reproduction operation includes at least one of a loop reproduction, a key change reproduction, a pitch change reproduction and a tempo change reproduction.

12. The audio reproducer as claimed in claim 1, wherein the audio reproduction part and the processing part are detachable each other.

13. The audio reproducer as claimed in claim 1, wherein the input terminal receives an audio signal generated by playing a musical instrument.
